(19) United States
(12) Patent Application Publication
(10) Pub. No.: US 2009/0283836 A1
(43) Pub. Date: Nov. 19, 2009

(54) CMOS STRUCTURE INCLUDING PROTECTIVE SPACERS AND METHOD OF FORMING THEREOF

(75) Inventors: Huilong Zhu, Poughkeepsie, NY (US); Xiaomeng Chen, Poughkeepsie, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 12/119,517

(22) Filed: May 13, 2008

(51) Int. Cl. H01L 29/786; H01L 29/423; H01L 21/336

(52) U.S. Cl. 257/369; 257/410; 438/287; 257/E29.132; 257/E29.275

(57) ABSTRACT

The present invention provides a semiconductor device includes a substrate including a semiconducting region and isolation regions, a gate structure including a high-k gate dielectric layer atop the semiconducting region of the substrate and a metal gate conductor layer atop the high-k gate dielectric; protective nitride spacers enclosing the high-k gate dielectric layer between the metal gate conductor layer and the semiconducting region of the substrate, the protective nitride spacers separating the isolation regions from the high-k dielectric; and a polysilicon gate conductor overlying the metal gate conductor layer and enclosing the protective nitride spacers between at least the high-k dielectric layer, the semiconducting region, and a portion of the polysilicon gate conductor.

### FIELD OF THE INVENTION

The present invention relates to semiconductor devices. More particularly, the present invention relates to semiconductor devices having protective spacers separating the isolation regions from the high-k dielectric.

### BACKGROUND OF THE INVENTION

Field effect transistors (FETs) are widely used in the electronics industry for switching, amplification, filtering, and other tasks related to both analog and digital electrical signals. Most common among these are metal-oxide-semiconductor field-effect transistors (MOSFET or MOS), in which a gate structure is energized to create an electric field in an underlying channel region of a semiconductor body, by which electrons are allowed to travel through the channel between a source region and a drain region of the semiconductor body. Complementary MOS (CMOS) devices have become widely used in the semiconductor industry, wherein both n-type and p-type (NMOS and PMOS) transistors are used to fabricate logic and other circuitry.

The source and drain regions of a MOS are typically formed by adding dopants to targeted regions of a semiconductor body on either side of the channel. A gate structure is formed above the channel, having a gate dielectric located over the channel and a gate conductor above the gate dielectric. The gate dielectric is an insulator material, which prevents large currents from flowing into the channel when a voltage is applied to the gate conductor, while allowing such an applied gate voltage to set up an electric field in the channel region in a controllable manner. Conventional MOS transistors typically include a gate dielectric formed by depositing or by growing silicon dioxide (SiO₂) or silicon oxynitride (SiON) over a silicon wafer surface, with doped polysilicon formed over the SiO₂ to act as the gate conductor.

Continuing trends in semiconductor device manufacturing include reduction in electrical device feature sizes (scaling), as well as improvements in device performance in terms of device switching speed and power consumption. MOS transistor performance may be improved by reducing the distance between the source and the drain regions under the gate conductor of the device, known as the gate or channel length, and by reducing the thickness of the layer of gate dielectric that is formed over the semiconductor surface. However, there are electrical and physical limitations on the extent to which the thickness of SiO₂ gate dielectrics can be reduced. For example, thin SiO₂ gate dielectrics are prone to gate tunneling leakage currents resulting from direct tunneling through the thin gate dielectric. In addition, there are conventional limitations on the ability to form thin dielectric films with uniform thickness. Furthermore, thin SiO₂ gate dielectric layers provide a poor diffusion barrier to dopants and may allow high boron dopant penetration from the underlying channel region of the semiconductor substrate during fabrication of the source and drain regions.

Recent MOS and CMOS transistor scaling efforts have accordingly focused on high-k dielectric materials having dielectric constants greater than that of SiO₂ (e.g., greater than about 3.9), which can be formed in a thicker layer than scaled SiO₂, and yet which produce equivalent field effect performance. The relative electrical performance of such high-k dielectric materials is often expressed as equivalent oxide thickness (EOT), because the high-k material layer may be thicker, while still providing the equivalent electrical effect of a much thinner layer of SiO₂. Since the dielectric constant “k” is higher than silicon dioxide, a thicker high-k dielectric layer can be employed to mitigate tunneling leakage currents, while still achieving the equivalent electrical performance of a thinner layer of thermally grown SiO₂.

### SUMMARY OF THE INVENTION

The present invention provides a method for forming a semiconductor device having a gate structure including a metal gate and a high-k dielectric layer (gate dielectric). Broadly, the method includes:

providing a substrate comprising a semiconducting region and isolation regions abutting the semiconducting region;

recessing an upper surface of the semiconducting region below an upper surface of the isolation regions to provide a recessed semiconducting surface;

forming a high-k dielectric layer atop the recessed semiconductor surface;

forming a metal gate conductor layer atop the high-k dielectric layer;

recessing the upper surface of the isolation regions to expose at least sidewalls of the high-k dielectric layer;

forming protective nitride spacers on at least the sidewalls of the high-k dielectric layer enclosing the high-k dielectric layer between the metal gate conductor layer and the semiconducting region, the protective nitride spacers separating the isolation regions from the high-k dielectric;

forming a polysilicon gate conductor overlying the metal gate conductor and enclosing the protective nitride spacers between at least the high-k dielectric layer, the semiconducting region, and a portion of the polysilicon gate conductor; and

forming source and drain regions in the substrate.

The high-k gate dielectric layer may be composed of HfO₂, ZrO₂, Al₂O₃, TiO₂, La₂O₃, SrTiO₃, LaAlO₃, Y₂O₃, SiO₂, nitrided SiO₂ or silicates, nitrides or nitrided silicates thereof. The metal gate conductor layer may be composed of TiN or TaN or TiAlN. A nitride layer may be present atop at least one isolation region.

The step of recessing the upper surface of the semiconducting region below the upper surface of the isolation regions may include an anisotropic etch process having a selective etch chemistry. Forming the polysilicon gate conductor may include depositing a first polysilicon layer atop the metal gate conductor layer and planarizing the polysilicon layer to provide the upper surface being substantially coplanar to the upper surface of the isolation regions, and depositing a second polysilicon layer following the formation of the protective nitride spacers.

The step of recessing the upper surface of the isolation regions to expose at least the sidewalls of the high-k dielectric layer can include recessing the upper surface of the isolation regions below the recessed semiconducting surface. The recessing of the upper surface of the isolation regions below the recessed semiconducting surface may provide an exposed portion of the semiconducting surface having an edge substantially aligned to an edge of the high-k gate dielectric layer.

The step of forming the protective nitride spacers on the sidewalls of the high-k dielectric layer includes depositing a nitride layer and etching the nitride layer to provide a protective nitride spacer that encloses the high-k dielectric layer. The high-k dielectric layer is separated from the isolation regions by the protective nitride spacers. The protective nitride spacers may be formed on the exposed portion of the semiconducting surface having the edge substantially aligned to the edge of the high-k gate dielectric layer. A portion of the protective nitride spacer that is separating the isolation region from the high-k dielectric layer may be in direct physical contact with an upper surface of the isolation region and extends to the high-k dielectric layer, in which a portion of the protective nitride spacer is in direct physical contact with a portion of the semiconducting region underlying the high-k dielectric layer. Depositing the nitride layer may include chemical vapor deposition (CVD) or physical vapor deposition (PVD). Etching the nitride layer to provide the protective nitride spacers may include reactive ion etch. The step of forming the source and drain regions may include implanting an N-type dopant and/or P-type dopant into the semiconducting substrate.

In another aspect, the present invention provides a semiconductor structure. Broadly, the semiconducting device includes;

a substrate including a semiconducting region and isolation regions,

a gate structure including a high-k gate dielectric layer atop the semiconducting region of the substrate and a metal gate conductor layer atop the high-k gate dielectric;

protective nitride spacers enclosing the high-k gate dielectric layer between the metal gate conductor layer and the semiconducting region of the substrate, the protective nitride spacers separating the isolation regions from the high-k dielectric; and

a polysilicon gate conductor overlying the metal gate conductor layer and enclosing the protective nitride spacers between at least the high-k dielectric layer, the semiconducting region, and a portion of the polysilicon gate conductor.

The high-k gate dielectric layer may include HfO₂, ZrO₂, Al₂O₃, TiO₂, La₂O₃, SrTiO₃, LaAlO₃, Y₂O₃, SiO₂, nitrided SiO₂ or silicates, nitrides or nitrided silicates thereof. The high-k gate dielectric may have a dielectric constant greater than about 4.0. The protective nitride spacers may be composed of nitride or oxynitride. In one embodiment, the substrate is composed of Si, Ge, SiGe, SiC, SiGeC, Ga, Gas, InAs, InP, other III/V or II/VI compound semiconductors, organic semiconductors, or layered semiconductors. The semiconductor device may be composed of an n-type doped source and drain regions positioned substantially adjacent to a portion of the substrate underlying the gate structure. The substrate may be composed of p-type doped source and drain regions substantially adjacent to a portion of the substrate underlying the gate structure.

The method may further includes forming a thin interface layer atop of the high-k dielectric layer. The interface layer may include La₂O₃ or Al₂O₃. In one embodiment, the thickness of the interface layer ranges from 0.1 nm to about 0.5 nm.

In another aspect, the present invention provides a CMOS device. Broadly, the CMOS device of the present invention includes:

a substrate comprising a first semiconductor region and a second semiconductor region, wherein the first semiconductor region is separated from the second semiconductor region by an isolation region;

an n-type semiconductor device on the first semiconductor region, the n-type type semiconductor device including a first gate structure and first spacers abutting the first gate structure, the first gate structure comprising a first high-k gate dielectric layer atop the first semiconducting region and a first metal gate atop the first high-k gate dielectric layer, wherein the first high-k gate dielectric layer is enclosed by the first nitride spacers, the first metal layer and the first semiconducting region, the first nitride spacers separating the isolation region from the first high-k dielectric layer; and

a p-type semiconductor device on the second semiconductor region, the p-type semiconductor device including a second gate structure and second spacers abutting the second gate structure, the second gate structure comprising a second high-k gate dielectric layer atop the second semiconducting region and a second metal gate atop the second high-k gate dielectric layer, wherein the second high-k gate dielectric layer is enclosed by the second nitride spacers, the second metal layer and the second semiconducting region, the second nitride spacers separating the isolation region from the second high-k dielectric layer.

### BRIEF DESCRIPTION OF THE DRAWINGS

The following detailed description, given by way of example and not intended to limit the invention solely thereto, will best be appreciated in conjunction with the accompanying drawings, wherein like reference numerals denote like elements and parts, in which:

FIG. 1 is a side cross sectional view of a complementary metal oxide semiconductor device (CMOS) along a plane perpendicular to the dimension defining the channel length, as measured from the source region to the drain region of the device, in accordance with the present invention.

FIG. 2 is a top view of a method step for forming a metal oxide semiconductor (MOS) device, wherein FIG. 2 depicts one embodiment of a substrate including a semiconducting portion and isolation regions, as used in accordance with the present invention.

FIG. 3 is a side cross sectional view of a method step for forming a metal oxide semiconductor (MOS) device along the section line A-A of FIG. 2, which is the plane perpendicular to the dimension defining the channel length, wherein FIG. 3 depicts one embodiment of a substrate including a semiconducting portion and isolation regions, as used in accordance with the present invention.

FIG. 4 is a top view of a method step for forming a metal oxide semiconductor (MOS) device, wherein FIG. 4 depicts one embodiment of forming a protective nitride spacer, as used in accordance with the present invention.

FIG. 5 is a side cross sectional view of a method step for forming a metal oxide semiconductor (MOS) device along section line A-A of FIG. 4, the plane perpendicular to the dimension defining the channel length, wherein FIG. 5 depicts one embodiment of forming a protective nitride spacer, as used in accordance with the present invention.

FIG. 6 is a top view depicting the formation of a polysilicon layer atop the structure depicted in FIGS. 4 and 5, in accordance with one embodiment of the present invention.

FIG. 7 is a side cross sectional view along section line A-A of FIG. 6, the plane perpendicular to the dimension defining the channel length, depicting one embodiment of forming a polysilicon layer atop the structure depicted in FIGS. 4 and 5, in accordance with the present invention.

FIG. 8 is a top view depicting forming source/drain regions, in accordance with one embodiment of the present invention.

FIG. 9 is a side cross sectional view along section line A-A of FIG. 8, the plane perpendicular to the dimension defining the channel length, depicting forming source/drain regions, in accordance with one embodiment of the present invention.

FIG. 10 is a side cross sectional view along section line 1-1 of FIG. 8, the plane parallel to the dimension defining the channel length, depicting forming the source/drain regions, in accordance with one embodiment of the present invention.

### DETAILED DESCRIPTION OF THE INVENTION

Detailed embodiments of the present invention are disclosed herein; however, it is to be understood that the disclosed embodiments are merely illustrative of the invention that may be embodied in various forms. In addition, each of the examples given in connection with the various embodiments of the invention are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the present invention.

The embodiments of the present invention relate to novel methods for forming gate structures, such as gate structures to semiconducting devices, e.g., gate structures to field effect transistors (FETs), such as metal oxide semiconductor (MOS) devices or complementary metal oxide semiconductor (CMOS) devices. When describing the inventive structures and methods, the following terms have the following meanings, unless otherwise indicated.

As used herein, “semiconductor device” refers to an intrinsic semiconductor material that has been doped, that is, into which a doping agent has been introduced, giving it different electrical properties than the intrinsic semiconductor. Doping involves adding dopant atoms to an intrinsic semiconductor, which changes the electron and hole carrier concentrations of the intrinsic semiconductor at thermal equilibrium. Dominant carrier concentrations in an extrinsic semiconductor classify it as either an n-type or p-type semiconductor. In intrinsic semiconductors the valence band and the conduction band are separated by the energy gap that is less than about 3.5 eV.

As used herein, a “P-type semiconductor” refers to the addition of trivalent impurities to an intrinsic semiconductor substrate that creates deficiencies of valence electrons, such as boron, aluminum or gallium to an intrinsic Si-containing substrate.

As used herein, an “N-type semiconductor” refers to the addition of pentavalent impurities that contributes free electrons to an intrinsic semiconductor substrate, such as antimony, arsenic or phosphorous impurities to an intrinsic Si-containing substrate.

A “gate structure” means a structure used to control output current (i.e., flow of carriers in the channel) of a semiconducting device through electrical or magnetic fields.

As used herein, the term “gate conductor” is a component of the gate structure that is composed of a conductive material and is overlying the gate dielectric.

As used herein, a “gate dielectric” is a layer of an insulator between the semiconductor device substrate and the gate conductor.

As used herein, “high K” denotes a dielectric material featuring a dielectric constant (k) higher than about 4.0.

As used herein, “low K” denotes a dielectric material featuring a dielectric constant (k) equal to 4.0 or less.

The terms “overlying”, “atop”, “positioned on” or “positioned atop” means that a first element, such as a first structure, e.g., a first layer, is present on a second element, such as a second structure, e.g., a second layer, wherein intervening elements, such as an interface structure, e.g., interface layer, may be present between the first element and the second element.

The term “direct physical contact” means that a first element, such as a first structure, e.g., first phase change material, and a second elements, such as a second structure, e.g., second phase change material, are connected without any intermediary conducting, insulating or semiconducting layers at the interface of the two materials.

As used herein, a “metal” is an electrically conductive material, wherein in metal atoms are held together by the force of a metallic bond; and the energy band structure of metal's conduction and valence bands overlap, and hence, there is no energy gap.

“Electrically conductive” as used through the present disclosure means a material having a room temperature conductivity of greater than 10⁻⁸ (Ω-m)⁻¹. As used herein, the terms

“Insulating” and “dielectric” denote a material having a room temperature conductivity of less than about 10⁻¹⁰ (Ω-m)⁻¹.

As used herein, “a conformal layer” is a deposited material having a thickness that remains the same regardless of the geometry of underlying features on which the layer is deposited, wherein the thickness of the layer does not deviate from greater than or less than 20% of an average value for the thickness of the layer.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left, “vertical”, “horizontal”, “top”, “bottom”, “beneath”, “underlying”, “below”, “overlying” and derivatives thereof shall relate to the invention, as it is oriented in the drawing figures.

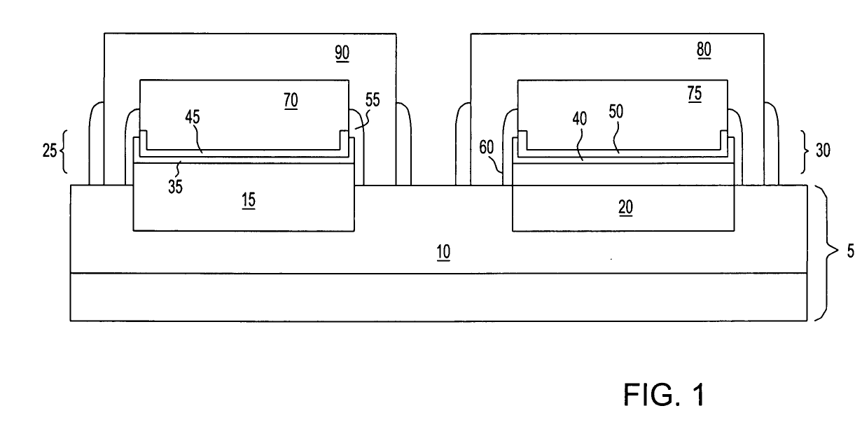

Reference is first made to FIG. 1, which is a pictorial representation (through a cross sectional view) showing one embodiment of a complementary metal oxide-semiconducting (CMOS) device, in accordance with the present invention. The complementary metal-oxide semiconducting (CMOS) device may include a substrate 5 including at least one semiconducting region 15, 20, wherein source and drain diffusion regions (not shown) are located in the substrate 5, which are separated from each other by a device channel. A gate structure 25, 30 comprising a high-k dielectric 35, 40, i.e., a gate dielectric, located atop the device channel, and a metal gate conductor 45, 50 located atop the high-k dielectric 35, 40 may be located in at least one semiconducting region 15, 20. The at least one semiconducting portion of the device may be the SOI (silicon on insulator) layer of semiconducting substrate including a buried oxide region.

The first semiconducting region 15 may include an n-type doped source and drain positioned substantially adjacent to a portion of the semiconducting substrate underlying a first gate structure 25. The second semiconducting region 20 may include a p-type doped source and drain substantially adjacent to a portion of the semiconducting substrate underlying the second gate structure 30. The n-type doped source and drain may form an n-type semiconductor device that is positioned on the first semiconductor region 15, which includes a first gate structure 25 and first protective nitride spacers 55 enclosed within the first gate structure 25. The p-type doped source and drain forms a p-type semiconductor device on the second semiconductor region 20 that includes a second gate structure 30 and second protective nitride spacers 60 enclosed within the second gate structure 30.

The first gate structure 25 may include a first high-k dielectric layer 35 atop the first semiconducting region 15 and a first metal gate conductor layer 45 atop the first high-k dielectric layer 35, wherein the first high-k dielectric layer 35 and an upper portion of the first semiconductor region 15 are separated from the isolation region 10 by the first protective nitride spacers 55. The first gate structure 25 may further include a first polysilicon gate conductor, wherein the first polysilicon gate conductor includes a first polysilicon layer 70 overlying the first metal gate conductor layer 45 and a second polysilicon layer 90 that overlies and encloses the first protective nitride spacers 55. The first high-k dielectric layer 35 may be enclosed between the first metal gate conductor layer 45, the first nitride protective spacers 55, and the first semiconducting region 15. In one embodiment, the second polysilicon layer 90 encloses the first protective nitride spacers 55 between at least the first high-k dielectric layer 35, the first semiconducting region 15, and a portion of the polysilicon gate conductor.

The n-type semiconductor device may include a first gate structure 25 including a first metal conductor layer 45 composed of titanium nitride (TiN) and a first high-k dielectric layer 35 composed of hafnium oxide (HfO₂), wherein a layer of aluminum oxide (La₂O₃) may be present at the interface of the first metal gate conductor layer 45 and the first high-k dielectric layer 35. The n-type semiconductor device may include a first gate structure 25 including a metal gate conductor layer 45 composed of tungsten nitride (WN) or TiAlN and a first high-k dielectric layer 35 composed of HfO₂.

The second gate structure 30 includes a second high-k dielectric layer 40 atop the second semiconducting region 20 and a second metal gate conductor layer 50 atop the second high-k dielectric layer 40, wherein the second high-k dielectric layer 40 and an upper portion of the second semiconductor region 20 are separated from the isolation region 10 by the second protective nitride spacers 60. The second high-k dielectric layer 40 may be enclosed by the second protective nitride spacers 60, the second metal gate conductor layer 50, and the second semiconducting region 20.

The second gate structure 30 may further include a second polysilicon gate conductor, wherein the second polysilicon gate conductor includes a second polysilicon layer 75 overlying the second metal gate conductor layer 50 and a second polysilicon layer 80 that overlies and encloses the second protective nitride spacers 60. In one embodiment, the second high-k dielectric layer 40 is enclosed between the second metal gate conductor layer 50, the second nitride protective spacers 60, and the second semiconducting region 20. The second polysilicon layer 80 may enclose the second protective nitride spacers 60 between at least the second high-k dielectric layer 40, the second semiconducting region 20, and a portion 81 of the polysilicon gate conductor.

The p-type semiconductor device may include a second gate structure 30 including a second metal gate conductor 50 composed of titanium nitride (TiN) and a second high-k dielectric 40 composed of hafnium oxide (HfO₂), wherein a layer of Al₂O₃ or tantalum oxide (TaO) may be present at the interface of the second metal gate conductor 50 and the layer of the second high-k dielectric 40. In another embodiment, the second metal gate conductor 50 composed of TaN and a second high-k dielectric 40 composed of hafnium oxide (HfO₂).

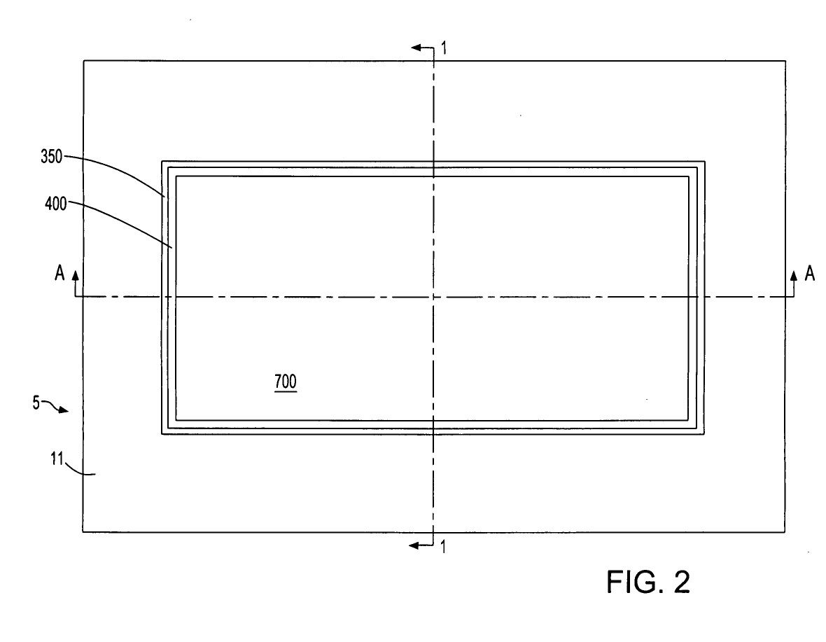

Although FIG. 1 depicts a CMOS device, the present invention is not intended to be limited solely to CMOS devices, as the present invention is equally applicable to devices including one or more of the same type devices. For examples, a metal oxide-semiconducting field effect transistor (MOSFET) device may be provided for only one or more n-type devices, or only one or more p-type devices. The various components of the structures shown in FIG. 1, as well as the process that can be used in forming the same, will now be described in greater detail referring FIGS. 2-10. It is noted that FIGS. 2-10 depict forming a single device, but the method disclosed below may be applied to produce CMOS devices, as depicted in FIG. 1, using block masks to selectively process a first region of the device, while not substantially effecting a second region of the device. It is further noted that FIGS. 2-10 depict forming a n-type device region, as described above, but are equally applicable for forming a p-type region, wherein the material selection and dopants are selected to correspond to the device type.

Referring to FIGS. 2-10, the inventive method may include providing a substrate 5 comprising a semiconducting region 150 and isolation regions 100 abutting the semiconducting region 150; recessing an upper surface of the semiconducting region 150 below an upper surface of the isolation regions 100 to provide a recessed semiconducting surface 150a; forming a layer of a high-k gate dielectric 350 atop the recessed semiconductor surface 150a; forming a layer of a metal gate conductor 400 atop the layer of the high-k gate dielectric 350; recessing the upper surface of the isolation regions 100 to expose at least the sidewalls of the layer of the high-k gate dielectric 350; forming protective nitride spacers 600 on at least the sidewalls of the layer of the high-k dielectric 350, wherein the protective nitride spacers 600 enclose the high-k gate dielectric 350 between the metal gate conductor 400 and the semiconducting region 150; forming a polysilicon gate conductor overlying the metal gate conductor 400 and enclosing the protective nitride spacers 600 between at least the high-k dielectric layer 350, the semiconducting region 150, and a portion of the polysilicon gate conductor; and forming source and drain regions in the substrate 5.

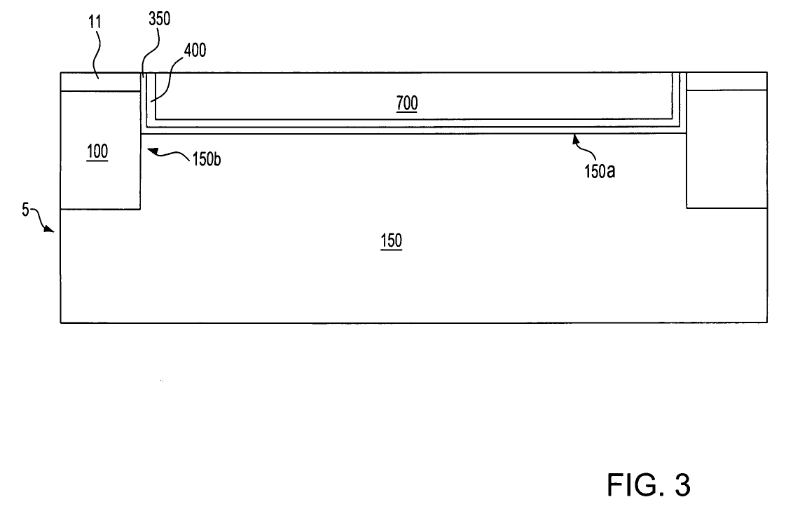

Referring to FIGS. 2 and 3, an initial structure is first provided including a substrate 5, such as a semiconducting substrate, and isolation regions 10. Each isolation region 10 may include a cap layer 11. The isolation regions 10 may be composed of an oxide containing composition, such as silicon oxide (SiO₂). The cap layer 11 may be composed of a nitride composition, such as silicon nitride (Si₃N₄).

The substrate 5 employed in the present invention may be composed of any semiconducting material including, but not limited to: Si, Ge, SiGe, SiC, SiGeC, Ga, GaAs, InAs, InP and all other III/V or II/VI compound semiconductors. The substrate 5 may also comprise an organic semiconductor or a layered semiconductor such as Si/SiGe, a silicon-on-insulator (SOI) or a SiGe-on-insulator (SGOI). In some embodiments of the present invention, it is preferred that the substrate 5 be composed of a Si-containing semiconductor material, i.e., a semiconductor material that includes silicon. The substrate 5 may be doped, undoped or contain doped and undoped regions therein. The substrate 5 may also include at least one doped (n- or p-) well region. For clarity, the doped regions are not specifically shown in the drawing of the present application.

The at least one isolation region 100 is typically formed into the substrate 5. The isolation region 100 may be a trench isolation region or a field oxide isolation region. The trench isolation region is formed utilizing a conventional trench isolation process well known to those skilled in the art. For example, lithography, etching and filling of the trench with a trench dielectric may be used in forming the trench isolation region. Optionally, a liner may be formed in the trench prior to trench fill, a densification step may be performed after the trench fill and a planarization process may follow the trench fill as well. The field oxide may be formed utilizing a so-called local oxidation of silicon process. Note that the at least one isolation region 100 provides isolation between neighboring semiconducting regions, typically required when the neighboring gates have opposite conductivities. The neighboring gate regions can have the same conductivity (i.e., both n- or p-type), or alternatively they can have different conductivities (i.e., one n-type and the other p-type). In one embodiment, the portion of the semiconducting substrate 5 that is positioned between two isolation regions 100 defines a semiconducting region.

The cap layer 11 may be formed atop the isolation region 100 using deposition methods, such as chemical vapor deposition (CVD). Chemical Vapor Deposition is a deposition process in which a deposited species is formed as a results of chemical reaction between gaseous reactants at greater than room temperature (25° C. to 600° C.); wherein solid product of the reaction is deposited on the surface on which a film, coating, or layer of the solid product is to be formed. Variations of CVD processes include, but not limited to, Atmospheric Pressure CVD (APCVD), Low Pressure CVD (LPCVD) and Plasma Enhanced CVD (EPCVD), Metal-Organic CVD (MOCVD) and combinations thereof may also be employed. The cap layer 11 may be composed of a nitride composition, such as silicon nitride (Si₃N₄) or silicon oxygen nitride. In one embodiment, the thickness, i.e., height, of the cap layer 11 is from about 20 to about 180 nm.

Still referring to FIGS. 2 and 3, after forming the at least one isolation region 100 and the cap layer 11 within the substrate, a first high-k gate dielectric layer 350 is formed on a surface of the semiconducting region of the substrate 5. Although FIGS. 2 and 3 depict only the first semiconducting region, it is noted that the following description is equally applicable to the second semiconducting region, wherein the region is processed to correspond to p-type and n-type devices as needed. Therefore, the first high-k dielectric layer and the second high-k dielectric layer will collectively be referred to as a high-k gate dielectric layer 350, and the first semiconducting region and the second semiconducting region are collectively referred to as semiconducting region 150.

Prior to depositing the high-k gate dielectric 350, the upper surface of the semiconducting region 150 is recessed (referred to as recessed upper surface 150a) using a selective etch process. In one embodiment of the present invention when the semiconducting region 150 is composed of a silicon containing composition and the cap layer 11 is composed of silicon nitride (Si₃N₄), the upper surface of the semiconducting region 13 is recessed by an anisotropic etch process, such as reactive ion etch, in which the etch chemistry removes the Si-containing composition of the semiconducting region 150 without substantially etching the silicon nitride cap layer 11. The selective etch process may produce a recess, in which the upper surface of the recessed semiconducting region 13 has a depth ranging from about 20 nm to about 40 nm, as measured from the top surface of the semiconducting region 150.

The high-k gate dielectric layer 350 can be formed by a thermal growth process, such as oxidation, nitridation or oxynitridation. In one example, the high-k gate dielectric layer 350 can be formed by a deposition process such as, for example, chemical vapor deposition (CVD), plasma-assisted CVD, metal organic chemical vapor deposition (MOCVD), atomic layer deposition (ALD), evaporation, reactive sputtering, chemical solution deposition and other like deposition processes. The high-k gate dielectric layer 350 can be deposited as a conformal layer on the recessed surface 150a of the semiconducting region 150 and the sidewalls of the isolation region 100 that is exposed when the upper surface of the semiconducting region 150 is recessed below the upper surface of the isolation regions 100.

The high-k gate dielectric layer 350 may be comprised of an insulating material having a dielectric constant of greater than about 4.0. In one embodiment, the high-k gate dielectric layer 350 has a dielectric constant greater than about 7.0. Specifically, the high-k gate dielectric layer 350 employed in the present invention includes, but not limited to: an oxide, nitride, oxynitride and/or silicate including metal silicates and nitrided metal silicates. The high-k gate dielectric 350 may be a Hf-based dielectric. Examples of Hf-based dielectrics include, but are not limited to: hafnium oxide (HfO₂), hafnium silicate (HfSiOₓ), Hf silicon oxynitride (HfSiON) or multilayers thereof. In one example, the Hf-based dielectric is composed of a mixture of HfO₂ and ZrO₂. The Hf-based dielectric can be replaced, or used in conjunction with, another dielectric material having a dielectric constant of greater than about 4.0, typically greater than about 7.0. In one embodiment, the Hf-based dielectric is a “high k” material whose dielectric constant is greater than about 10.0.

In one example of the present invention, the Hf-based dielectric is hafnium oxide that is formed by MOCVD were a flow rate of about 70 to about 90 mgm of hafnium-tetrabutoxide (a Hf-precursor) and a flow rate of O₂ of about 250 to about 350 sccm are used. The deposition of Hf oxide occurs using a chamber pressure between 0.3 and 0.5 Torr and a substrate temperature of between 400° and 500° C.

The Hf-based dielectric may be hafnium silicate which is formed by MOCVD using the following conditions (i) a flow rate of the precursor Hf-tetrabutoxide of between 70 and 90 mg/m, a flow rate of O₂ between 25 and 100 sccm, and a flow rate of SiH₄ of between 20 and 60 sccm; (ii) a chamber pressure between 0.3 and 0.5 Torr, and (iii) a substrate temperature between 400° and 500° C.

The high-k gate dielectric layer 350 may also be comprised of an oxide such as, for example, ZrO₂, Al₂O₃, TiO₂, La₂O₃, SrTiO₃, LaAlO₃, Y₂O₃ and mixtures thereof.

The physical thickness of the high-k gate dielectric layer 350 may vary, but in one embodiment of the present invention, the high-k gate dielectric layer 350 has a thickness ranging from about 0.5 nm to about 10 nm, with a thickness from about 0.5 to about 3 nm being more typical. It may be deposited above a thin (on the order of about 0.1 to about 1.5 nm) layer of silicon oxide or silicon oxynitride that is first deposited on the substrate 5.

Still referring to FIGS. 2 and 3, in a following process step, the first metal gate conductor layer 400 is deposited atop the high-k gate dielectric layer 350. Although FIGS. 2 and 3 depict only the first semiconducting region, it is noted that the following description is equally applicable to the second semiconducting region, wherein the region is processed to correspond to p-type and n-type devices as needed. Therefore, the first metal gate conductor and the second metal gate conductor will collectively be referred to as metal gate conductor 350.

The metal gate conductor layer 400 may be a workfunction defining metal. By “workfunction defining metal” it is meant a metal layer that can be used to adjust or set the workfunction of the gate stack. For n-type workfunctions, the workfunction defining metal comprises at least one element from Groups IIIB, IVB or VB of the Periodic Table of Elements (the nomenclature of the elements is based on the CAS version). Elements within the Lanthanide Series (e.g., La, Ce, Pr, Nd, Pm, Sm, Eu, Gd, Tb, Dy, Ho, Er, Tm, Yb or Lu) also contemplated herein. Illustrative examples of metal that can be used in providing an n-type workfunction to a conductive electrode comprise, but are not limited to: Sc, Y, La, Zr, Hf, V, Nb, Ta, Ti and elements from the Lanthanide Series. In one embodiment, the workfunction defining metal used in providing the n-type workfunction shift is one of elements from the Lanthanide group. For p-type workfunctions, the workfunction defining metal comprises at least one element from Groups VIB, VIIB and VIII of the Periodic Table of Elements (the nomenclature of the elements is based on the CAS version). Illustrative examples of metals that can be used in providing a p-type workfunction to a conductive electrode comprise, but are not limited to: Re, Fe, Ru, Co, Rh, Ir, Ni, Pd, and Pt. The workfunction defining metal that can be used in providing the p-type workfunction shift is one of Re, Ru or Pt.

The metal gate conductor layer 400 may include Ti, Zr, Hf, V, Nb or Ta, with Ti or Ta being highly preferred. In one embodiment, the metal gate conductor layer 400 includes TiN or TaN. In an even further embodiment, the metal gate conductor layer 400 may also be composed of a ternary alloy of Ti-alkaline earth metal-N, a ternary alloy of Ta-alkaline earth metal-N or a stack of a ternary alloy of Ti-alkaline earth metal-N or Ta-alkaline earth metal-N that is mixed with another one of the above mentioned alkaline earth metal-containing materials.

In one embodiment of the present invention, the metal gate conductor layer 400 is TiN that is deposited by evaporating Ti from an effusion cell held in the range of 1550° to 1900° C., and using an atomic/excited beam of nitrogen that is passed through a remote radio frequency source. In another embodiment, the metal gate conductor 400 layer is TiN that is deposited by evaporating Ti from an effusion cell held in the range of 1600° C. to 1750° C., and using an atomic/excited beam of nitrogen that is passed through a remote radio frequency source. In one embodiment, the substrate temperature can be around 300° C., and the nitrogen flow rate can be between 0.5 sccm and 3.0 sccm. The nitrogen flow rate depends upon the specifics of the deposition chamber, in particularly, the pumping rate on the chamber. The TiN may be deposited, in other ways, as well, such as chemical vapor deposition or sputtering.

The metal gate conductor layer 400 can be deposited using CVD, PVD, ALD, sputtering or evaporation. In one embodiment, the physical thickness of the metal gate conductor layer 400 ranges from about 0.5 nm to about 200 nm, with a thickness from about 5 to about 80 nm being more typical.

Referring to FIGS. 2 and 3, in a following process step, the polysilicon gate conductor is formed overlying the metal gate conductor layer 400 and enclosing the protective nitride spacer 600. The polysilicon gate conductor may be composed of a first polysilicon layer 700 and a second polysilicon layer 900. A first layer of polysilicon 700 (i.e., polycrystalline silicon) may be formed atop the metal gate conductor layer 400 utilizing a deposition process such as, for example, physical vapor deposition, CVD or evaporation.

The first layer of polysilicon 700 may be doped or undoped. If doped, an in-situ doping deposition process may be employed in forming the same. Alternatively, a doped polysilicon layer 700 can be formed by deposition, ion implantation and annealing. Illustrative examples of dopant ions include As, P, B, BF2, Sb, Bi, In, Al, Ga, Tl or mixtures thereof. In one embodiment, doses for the ion implants are 1E14 (=1×10¹⁴) atoms/cm² to 1E16 (=1×10¹⁶) atoms/cm². In another embodiment, the does for the ion implants are 1E15 atoms/cm² to 5E 15 atoms/cm².

In a following process step, the first layer of polysilicon 700 is planarized stopping of the cap layer 11 to provide a first polysilicon layer 700 overlying the metal gate conductor layer 400. In one embodiment, the upper surface of the planarized polysilicon 700 is coplanar with the upper surface of the cap layer 11 Planarization is a material removal process that employs at least mechanical forces, such as frictional media, to produce a planar surface. In one embodiment, the layer of polysilicon is planarized by chemical mechanical planarization (CMP). Chemical mechanical planarization (CMP) is a material removal process using both chemical reactions and mechanical forces to remove material and planarize a surface. In one embodiment, the polysilicon layer 700 has a vertical thickness ranging from about 20 nm to about 180 nm. In another embodiment, the polysilicon layer 700 has a vertical thickness ranging from about 40 to about 150 nm.

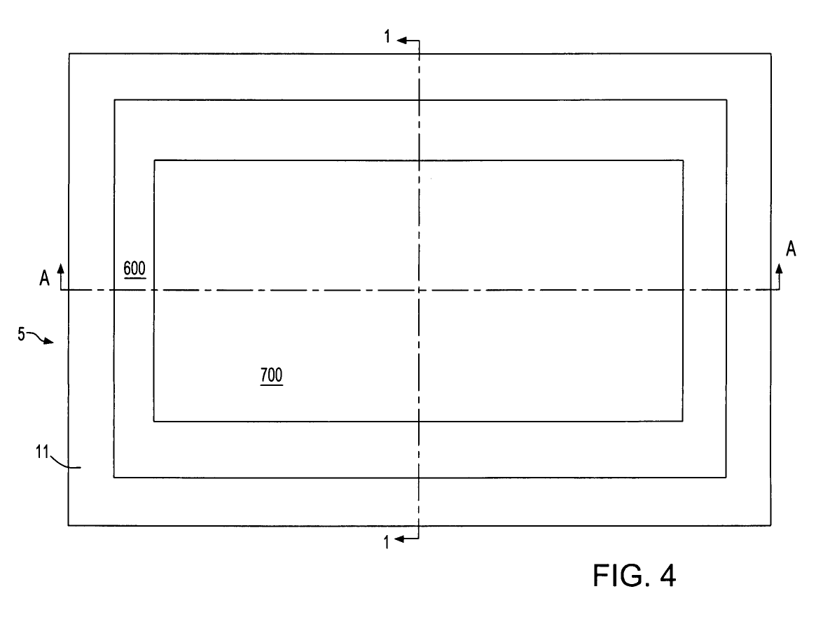

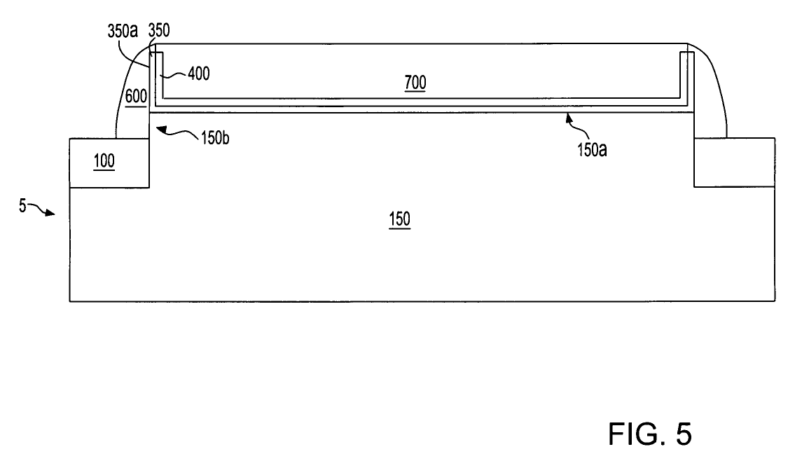

FIGS. 4 and 5 depict one embodiment of forming a protective nitride spacer 600. Although FIGS. 4 and 5 depict only the first semiconducting region, it is noted that the following description is equally applicable to the second semiconducting region, wherein the region is processed to correspond to p-type and n-type devices as needed. Therefore, the first protective nitride spacer 55 and the second protective nitride spacer 60 are collectively referred to as protective nitride spacers 600.

The protective nitride spacers 600 may prevent the growth of gate dielectrics that typically occurs in thermal annealing of high-k dielectrics. More specifically, the protective nitride spacers 600 protect from the growth of the high-k dielectrics, i.e., high-k gate dielectric, by enclosing the high-k gate dielectric 350 between the recessed surface 150a of the semiconducting region 150, metal gate conductor 400, and the protective nitride spacers 600, wherein the high-k dielectric 350 is separated from the isolation regions by the protective nitride spacers 600.

Prior to forming the protective nitride spacers 600, the upper surface of the isolation regions 100 are recessed to expose at least the sidewalls 350a of the high-k gate dielectric 350. The surface of the isolation regions 100 are recessed to expose the sidewalls 150b of the semiconducting region 150.

The length of the sidewalls 150b of the semiconducting region 15 exposed after recessing the upper surface of the isolation regions 100 may range from about 20 nm to about 40 nm. In another embodiment, the length of the sidewalls 150b of the semiconducting region 150 exposed after recessing the upper surface of the isolation regions 100 ranges from about 25 nm to about 35 nm.

The upper surface of the isolation regions 100 is recessed using an anisotropic etch process, such as reactive ion etch. As used herein, an “anisotropic etch process” denotes a material removal process in which the etch rate in the direction normal to the surface to be etched is much higher than in the direction parallel to the surface to be etched. Reactive ion etching is a form of plasma etching in which during etching the surface to be etched is placed on the RF powered electrode, wherein the surface to be etched takes on a potential that accelerates an etching species that is extracted from a plasma towards the surface to be etched, in which the chemical etching reaction is taking place in the direction normal to the surface.

The upper surface of the isolation regions 100 may be recessed using an etch process, in which the high-k gate dielectric 350 is protected by a block mask. The block mask may comprise soft and/or hardmask materials and can be formed using deposition, photolithography and etching. In one embodiment, the block mask comprises a photoresist. A photoresist block mask can be produced by applying a blanket photoresist layer, exposing the blanket photoresist layer to a pattern of radiation, and then developing the pattern into the photoresist layer utilizing conventional resist developer, wherein the remaining portion of the photoresist layer is overlying the high-k gate dielectric layer 350 and the isolation regions 100 are exposed.

The block mask can be a hardmask material. Hardmask materials include dielectric systems that may be deposited by chemical vapor deposition (CVD) and related methods. Typically, the hardmask composition includes silicon oxides, silicon carbides, silicon nitrides, silicon carbonitrides, etc. Spin-on dielectrics may also be utilized as a hardmask material including, but not limited to: silsequioxanes, siloxanes, and boron phosphate silicate glass (BPSG). A block mask comprising a hardmask material may be formed by blanket depositing a layer of hardmask material; providing a patterned photoresist atop the layer of hardmask material; and then etching the layer of hardmask material to provide a block mask protecting the high-k gate dielectric layer 350.

Recessing the upper surface of the isolation regions 100 may include a selective etch process, in which the cap layer 11 is first removed selective to the isolation region 100, and then the isolation region 100 is recessed, while the high-k gate dielectric layer 350 is protected by the block mask. Following etching the block mask is removed.

Still referring to FIGS. 4 and 5, in a following step, the protective nitride spacers 600 are formed on at least the sidewalls 350a of the high-k gate dielectric 350. The protective nitride spacers 600 are in direct physical contact with the high-k gate dielectric 350. The protective nitride spacers 600 may enclose the high-k gate dielectric 350 between the metal gate conductor 400 and the semiconducting region 150. The protective nitride spacers 600 separate the high-k dielectric layer 350 from the isolation region 100. In one embodiment, the protective nitride spacers 600 are in direct physical contact with a portion of the isolation region 100, such as an upper surface of the isolation region. In one embodiment, in which the upper surface of the isolation region 100 is recessed relative to the upper surface of the semiconducting region 150, a portion of the protective nitride spacer 600 that is separating the isolation region 200 from the high-k dielectric layer 350 is in direct physical contact with a portion of the semiconducting region 150 that is underlying the high-k dielectric 350.

The protective nitride spacers 600 may be comprised of a dielectric material such as an oxide, nitride, oxynitride and/or any combination thereof. In one embodiment, the protective nitride spacers 600 are composed of silicon nitride (Si₃N₄).

The protective nitride spacer 600 is formed by deposition and etching. The protective nitride spacers 600 have a width ranging from about 5 nm to about 30 nm. In another embodiment, the protective nitride spacers 600 have a width ranging from about 10 nm to about 20 nm. The protective nitride spacers 600 have a height ranging from about 40 nm to about 80 nm. In another embodiment, the protective nitride spacers 600 have a height ranging from about 50 nm to about 70 nm.

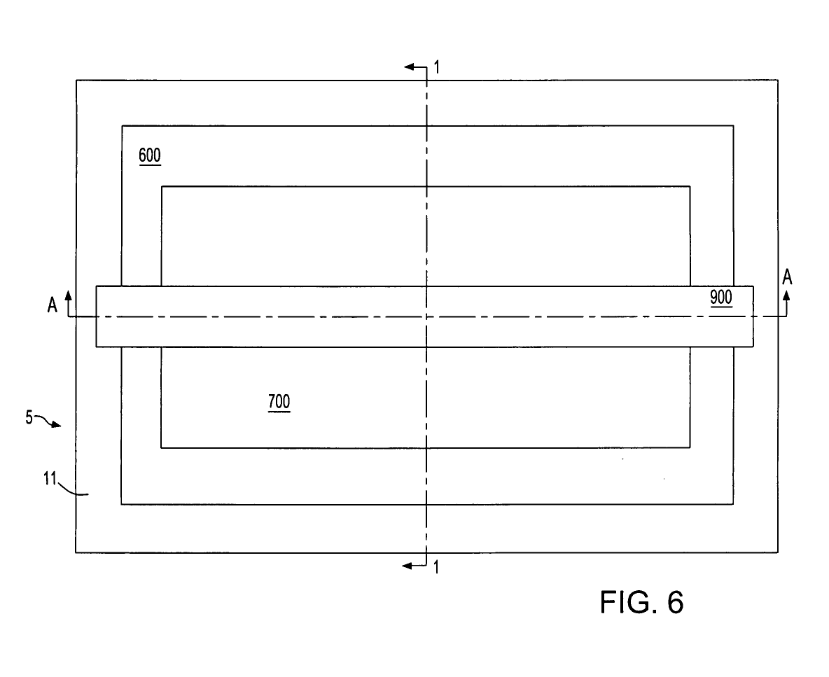

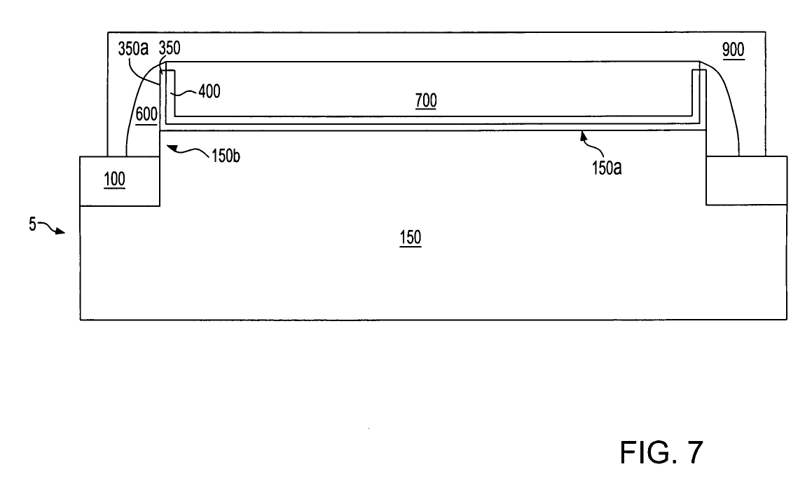

Referring to FIGS. 6 and 7, in one embodiment a blanket layer of polysilicon 900 may be formed atop the structure depicted in FIGS. 4 and 5 utilizing a deposition process such as, for example, physical vapor deposition or chemical vapor deposition. In one embodiment, the blanket layer of polysilicon provides the second polysilicon layer 900 that encloses the protective nitride spacers 600 between at least the high-k dielectric layer 350, semiconducting region 150, and a portion 901 of the second polysilicon layer 900. In one embodiment, the blanket layer of polysilicon is composed of doped polysilicon similar to that described above in reference to the first polysilicon layer 700.

A dielectric cap layer may be formed atop the blanket layer of polysilicon, wherein the blanket polysilicon layer 900 and dielectric cap layer are then patterned by lithography and etched so as to provide the patterned second polysilicon layers 80, 90 of the polysilicon gate conductors, as depicted in FIG. 1.

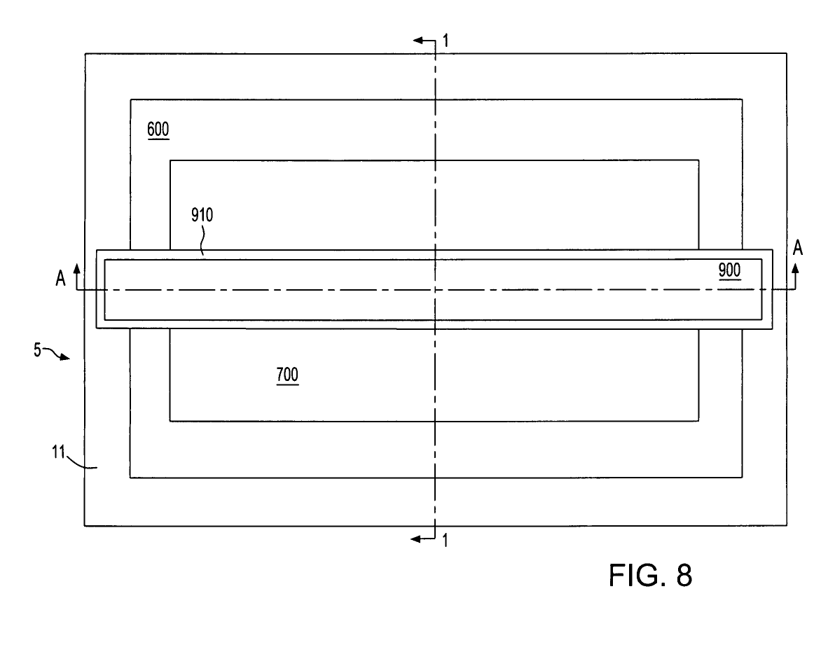

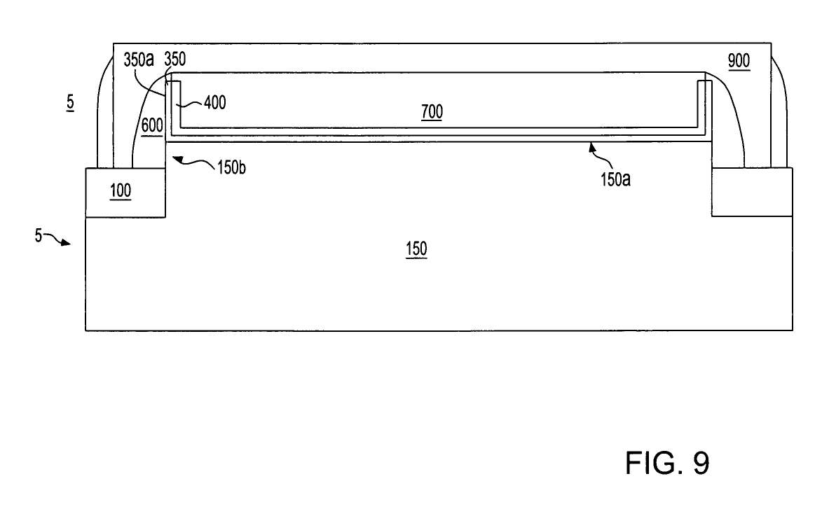

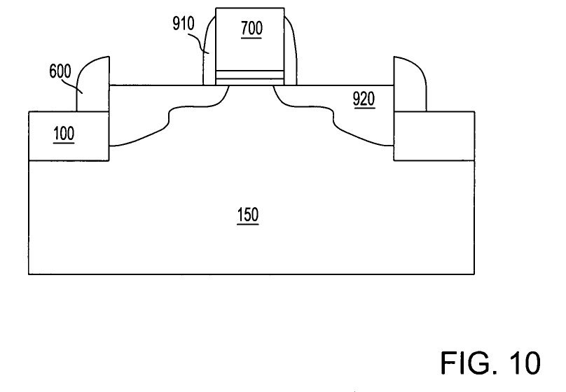

Referring to FIGS. 8, 9 and 10, in a following process step, the at least one dopant spacer 910 is formed on exposed sidewalls of the second polysilicon layer 900 of the polysilicon gate conductor. It is noted that FIG. 10 does not depict the polysilicon layer 900 of the polysilicon gate conductor, since this feature is clearly depicted in FIGS. 8 and 9. The at least one dopant spacer 910 is comprised of an insulator such as an oxide, nitride, oxynitride and/or any combination thereof. The at least one dopant spacer 910 is formed by deposition and etching. It is noted that in some embodiments of the present invention, the height of the protective nitride spacer 600 (See FIGS. 8-10) may be reduced during the etch step that produces the dopant spacer 910 in the portions of the protective nitride spacer 600 that are not underlying the patterned gate stacks of the blanket polysilicon layer 900. The width of the at least one dopant spacer 910 must be sufficiently wide enough such that the source and drain silicide contacts (to be subsequently formed) do not encroach underneath the edges of the gate structure. Typically, the source and drain silicide does not encroach underneath the edges of the gate stack when the at least one spacer has a width, as measured at the bottom, from about 15 to about 80 nm.

After dopant spacer 910 formation, source and drain diffusion regions 920 are formed into the substrate, as depicted in FIG. 10. The source and drain diffusion regions 920 are formed utilizing ion implantation and an annealing step. The annealing step serves to activate the dopants that were implanted by the previous implant step. The conditions for the ion implantation and annealing are well known to those skilled in the art.

Source and drain silicide contacts (not shown) are then formed using a salicide process which includes the steps of depositing a silicide metal on an exposed surface of the substrate that includes the source and drain diffusion regions, optionally depositing an oxygen diffusion barrier material such as TiN on the silicide metal, first annealing to form a silicide, selective etching any non-reacted metal including barrier material if used and, if needed, performing a second annealing step. When the semiconductor substrate does not comprise silicon, a layer of silicon (not shown) can be grown atop the exposed surface of the semiconductor substrate and can be used in forming the source and drain silicide contacts.

The silicide metal used in forming the source and drain silicide contacts comprises any metal that is capable of reacting with silicon to form a metal silicide. Examples of such metals include, but are not limited to: Ti, Ta, W, Co, Ni, Pt, Pd and alloys thereof. In one embodiment, Co is a preferred metal. In such an embodiment, the second annealing step is required. In another embodiment, Ni or Pt is preferred. In this embodiment, the second annealing step is typically not performed.

The metal used in forming the source and drain silicides may be deposited using any conventional deposition process including, for example, sputtering, chemical vapor deposition, evaporation, chemical solution deposition, plating and the like.

The first anneal is typically performed at lower temperatures than the second annealing step. Typically, the first annealing step, which may, or may not, form a high resistance silicide phase material, is performed at a temperature from about 300° to about 600° C. using a continuous heating regime or various ramp and soak heating cycles. More preferably, the first annealing step is performed at a temperature from about 350° to about 550° C. The second annealing step is performed at a temperature from about 600° C. to about 800° C. using a continuous heating regime or various ramp and soak heating cycles. More preferably, the second annealing step is performed at a temperature from about 650° C. to about 750° C. The second anneal typically converts the high resistance silicide into a silicide phase of lower resistance.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What we claim as new is:

1. A semiconducting device comprising;
a substrate including a semiconducting region and isolation regions;
a gate structure including a high-k gate dielectric layer atop the semiconducting region of the substrate and a metal gate conductor layer atop the high-k gate dielectric;
protective nitride spacers enclosing the high-k gate dielectric layer between the metal gate conductor layer and the semiconducting region of the substrate, the protective nitride spacers separating the isolation regions from the high-k dielectric; and
a polysilicon gate conductor overlying the metal gate conductor layer and enclosing the protective nitride spacers between at least the high-k dielectric layer, the semiconducting region, and a portion of the polysilicon gate conductor.

2. The semiconducting device of claim 1, wherein the high-k gate dielectric layer comprises HfO₂, ZrO₂, Al₂O₃, TiO₂, La₂O₃, SrTiO₃, LaAlO₃, Y₂O₃, SiO₂, nitrided SiO₂ or silicates, nitrides or nitrided silicates thereof.

3. The semiconducting device of claim 1, wherein the high-k gate dielectric layer has a dielectric constant greater than about 4.0.

4. The semiconducting device of claim 1, wherein the protective nitride spacers comprise silicon nitride or silicon oxynitride.

5. The semiconductor device of claim 1, wherein the polysilicon gate conductor comprises doped polysilicon.

6. The semiconductor device of claim 1, wherein the substrate comprises n-type doped source region and drain region substantially adjacent a portion of the substrate underlying the gate stack.

7. The semiconductor structure of claim 1, wherein the substrate comprises p-type doped source region and drain region substantially adjacent a portion of the substrate underlying the gate stack.

8. A CMOS device comprising:
a substrate comprising a first semiconductor region and a second semiconductor region, wherein the first semiconductor region is separated from the second semiconductor region by an isolation region;
an n-type semiconductor device on the first semiconductor region, the n-type type semiconductor device including a first gate stack and first spacers abutting the first gate stack, the first gate stack comprising a first high-k gate dielectric atop the first semiconducting region and a first metal gate atop the first high-k gate dielectric, wherein the first high-k gate dielectric is enclosed by the first spacers, the first metal layer and the first semiconducting region, the first nitride spacers separating the isolation region from the first high-k dielectric; and
a p-type semiconductor device on the second semiconductor region, the p-type semiconductor device including a second gate stack and second spacers abutting the second gate stack, the second gate stack comprising a second high-k gate dielectric atop the second semiconducting region and a second metal gate atop the second high-k gate dielectric, wherein the second high-k gate dielectric is enclosed by the second spacers, the second metal layer and the second semiconducting region, the second spacers nitride separating the isolation region from second high-k dielectric.

9. A method of forming a semiconducting device comprising:
providing a substrate comprising a semiconducting region and isolation regions abutting the semiconducting region;
recessing an upper surface of the semiconducting region below an upper surface of the isolation regions to provide a recessed semiconducting region;
forming a high-k dielectric layer atop the recessed semiconductor region;
forming a metal gate conductor layer atop the high-k dielectric layer;
forming a polysilicon layer atop the metal gate conductor layer having an upper surface coplanar to an upper surface of the isolation regions;
recessing the upper surface of the isolation regions to expose at least sidewalls of the high-k dielectric layer;
forming protective nitride spacers on at least the sidewalls of the high-k dielectric layer enclosing the high-k dielectric layer between the metal gate conductor layer and the semiconducting region, the protective nitride spacers separating the isolation regions from the high-k dielectric layer;
forming a polysilicon gate conductor overlying the metal gate conductor layer and enclosing the protective nitride spacers between at least the high-k dielectric layer, the semiconducting region, and a portion of the polysilicon gate conductor; and
forming a source region and a drain region in the substrate.

10. The method of claim 9, wherein a portion of the protective nitride spacer that is separating the isolation regions from the high-k dielectric layer is in direct physical contact with an upper surface of the isolation regions and extends to the high-k dielectric layer, in which a portion of the protective nitride spacer is in direct physical contact with a portion of the semiconducting region underlying the high-k dielectric layer.

11. The method of claim 9, wherein the high-k dielectric layer comprises HfO₂, ZrO₂, Al₂O₃, TiO₂, La₂O₃, SrTiO₃, LaAlO₃, Y₂O₃, SiO₂, nitrided SiO₂ or silicates, nitrides or nitrided silicates thereof.

12. The method of claim 9, wherein the metal gate conductor layer comprises TiN, TaN, WN or TiAlN.

13. The method of claim 9, wherein the recessing of the upper surface of the semiconducting region below the upper surface of the isolation regions comprises an anisotropic etch selective.

14. The method of claim 9 further comprising forming a thin interface layer atop of the high-k dielectric layer.

15. The method of claim 14, wherein said interface layer comprises La₂O₃ or Al₂O₃.

16. The method of claim 14, wherein the thickness of said interface layer ranges from about 0.1 nm to about 0.5 nm.

17. The method of claim 9, wherein the forming of the polysilicon gate conductor overlying the metal gate conductor layer comprises forming a first polysilicon layer having an upper surface substantially coplanar to the upper surface of the isolation regions and following formation of the protective nitride spacers forming a second polysilicon layer overlying and enclosing the protective nitride spacers.

18. The method of claim 9, wherein the recessing of the upper surface of the isolation regions to below to expose at least sidewalls of the high-k dielectric layer comprises recessing the upper surface of the isolation regions below the recessed surface of the semiconducting regions.

19. The method of claim 9, wherein the forming of the protective nitride spacers on the at least the sidewalls of the high-k dielectric layer comprise depositing a nitride and etching the nitride.

20. The method of claim 9, wherein the forming of the source region and drain region comprises implanting an N-type dopant or P-type dopant into the semiconducting substrate.
